(19) United States
(12) Patent Application Publication
(10) Pub. No.: US 2025/0374604 A1
(43) Pub. Date: Dec. 4, 2025

(54) SEMICONDUCTOR DEVICE STRUCTURE WITH NANOSTRUCTURE AND METHOD FOR FORMING THE SAME

(71) Applicant: Taiwan Semiconductor Manufacturing Co., Ltd., Hsinchu (TW)

(72) Inventors: Yu-Jiun Peng, Hsinchu (TW); Yi-Hsin Lee, Taichung City (TW); Kai-Min Chien, New Taipei City (TW); Chun-Ming Yang, Taipei City (TW); Tsai-Jhen Kuo, Kaohsiung City (TW); Ming-Chang Wen, Kaohsiung City (TW)

(21) Appl. No.: 18/823,236

(22) Filed: Sep. 3, 2024

Related U.S. Application Data
(60) Provisional application No. 63/655,147, filed on Jun. 3, 2024.

(51) Int. Cl. H01L 29/423; H01L 21/306; H01L 21/8234; H01L 27/088; H01L 29/06; H01L 29/66; H01L 29/775; H01L 29/786

(52) U.S. Cl. CPC H10D 30/6735; H01L 21/30604; H10D 30/014; H10D 30/43; H10D 30/6757; H10D 62/121; H10D 84/0128; H10D 84/0151; H10D 84/038; H10D 84/83

(57) ABSTRACT

A method for forming a semiconductor device structure is provided. The method includes providing a substrate, a first nanostructure, a second nanostructure, and a first gate stack. The first nanostructure is between the substrate and the second nanostructure, and the first gate stack is wrapped around the first nanostructure and the second nanostructure. The method includes removing the first gate stack and end potions of the first nanostructure. The method includes partially removing the second nanostructure to round a first corner of the second nanostructure. The first corner becomes a first rounded corner after the second nanostructure is partially removed. The method includes removing the first nanostructure. The method includes forming a second gate stack over the substrate and wrapped around the second nanostructure.

### PRIORITY CLAIM AND CROSS-REFERENCE

This application claims the benefit of U.S. Provisional Application No. 63/655,147, filed on Jun. 3, 2024, and entitled “Sheet Rounding Tuning by Multi Step Sheet Formation”, the entirety of which is incorporated by reference herein.

### BACKGROUND

The semiconductor integrated circuit (IC) industry has experienced rapid growth. Technological advances in IC materials and design have produced generations of ICs. Each generation has smaller and more complex circuits than the previous generation. However, these advances have increased the complexity of processing and manufacturing ICs.

In the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs.

However, since feature sizes continue to decrease, fabrication processes continue to become more difficult to perform. Therefore, it is a challenge to form reliable semiconductor devices at smaller and smaller sizes.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, the dimensions of the various features may be arbitrarily increased or reduced for clarity of discussion.

FIGS. 1A-1E are cross-sectional views of various stages of a process for forming a semiconductor device structure, in accordance with some embodiments.

FIG. 1A-1 is a top view of the semiconductor device structure of FIG. 1A, in accordance with some embodiments.

FIG. 1A-2 is a cross-sectional view illustrating the semiconductor device structure along a sectional line X-X′ in FIG. 1A-1, in accordance with some embodiments.

FIG. 1E-1 is a top view of the semiconductor device structure of FIG. 1E, in accordance with some embodiments.

FIG. 2A is a cross-sectional view illustrating the semiconductor device structure along a sectional line X-X′ in FIG. 1E-1, in accordance with some embodiments.

FIGS. 2A-2C are cross-sectional views of various stages of a process for forming a semiconductor device structure, in accordance with some embodiments.

FIG. 2C-1 is a top view of the semiconductor device structure of FIG. 2C, in accordance with some embodiments.

FIG. 2C-2 is a cross-sectional view illustrating the semiconductor device structure along a sectional line Y-Y′ in FIG. 2C-1, in accordance with some embodiments.

FIGS. 3A-3D are cross-sectional views of various stages of a process for forming a semiconductor device structure, in accordance with some embodiments.

FIG. 3C-1 is a top view of the semiconductor device structure of FIG. 3C, in accordance with some embodiments.

FIG. 3C-2 is a cross-sectional view illustrating the semiconductor device structure along a sectional line X-X′ in FIG. 3C-1, in accordance with some embodiments.

FIG. 3D-1 is a top view of the semiconductor device structure of FIG. 3D, in accordance with some embodiments.

FIG. 3D-2 is a cross-sectional view illustrating the semiconductor device structure along a sectional line X-X′ in FIG. 3D-1, in accordance with some embodiments.

FIGS. 4A-4H are cross-sectional views of various stages of a process for forming a semiconductor device structure, in accordance with some embodiments.

FIG. 4A-1 is a top view of the semiconductor device structure of FIG. 4A, in accordance with some embodiments.

FIG. 4A-2 is a cross-sectional view illustrating the semiconductor device structure along a sectional line X-X′ in FIG. 4A-1, in accordance with some embodiments.

FIG. 4G-1 is a top view of the semiconductor device structure of FIG. 4G, in accordance with some embodiments.

FIG. 4G-2 is a cross-sectional view illustrating the semiconductor device structure along a sectional line X-X′ in FIG. 4G-1, in accordance with some embodiments.

FIG. 4H-1 is a top view of the semiconductor device structure of FIG. 4H, in accordance with some embodiments.

FIG. 4H-2 is a cross-sectional view illustrating the semiconductor device structure along a sectional line X-X′ in FIG. 4H-1, in accordance with some embodiments.

FIGS. 5A-5D are cross-sectional views of various stages of a process for forming a semiconductor device structure, in accordance with some embodiments.

FIG. 5C-1 is a top view of the semiconductor device structure of FIG. 5C, in accordance with some embodiments.

FIG. 5C-2 is a cross-sectional view illustrating the semiconductor device structure along a sectional line X-X′ in FIG. 5C-1, in accordance with some embodiments.

FIG. 5D-1 is a top view of the semiconductor device structure of FIG. 5D, in accordance with some embodiments.

FIG. 5D-2 is a cross-sectional view illustrating the semiconductor device structure along a sectional line X-X′ in FIG. 5D-1, in accordance with some embodiments.

FIGS. 6A-6D are cross-sectional views of various stages of a process for forming a semiconductor device structure, in accordance with some embodiments.

FIG. 6C-1 is a top view of the semiconductor device structure of FIG. 6C, in accordance with some embodiments.

FIG. 6C-2 is a cross-sectional view illustrating the semiconductor device structure along a sectional line X-X′ in FIG. 6C-1, in accordance with some embodiments.

FIG. 6D-1 is a top view of the semiconductor device structure of FIG. 6D, in accordance with some embodiments.

FIG. 6D-2 is a cross-sectional view illustrating the semiconductor device structure along a sectional line X-X′ in FIG. 6D-1, in accordance with some embodiments.

FIG. 7A is a cross-sectional view of a semiconductor device structure, in accordance with some embodiments.

FIG. 7B is a top view of the semiconductor device structure of FIG. 7A, in accordance with some embodiments.

FIG. 7C is a cross-sectional view illustrating the semiconductor device structure along a sectional line X-X′ in FIG. 7B, in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Furthermore, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “substantially” in the description, such as in “substantially flat” or in “substantially coplanar”, etc., will be understood by the person skilled in the art. In some embodiments the adjective substantially may be removed. Where applicable, the term “substantially” may also include embodiments with “entirely”, “completely”, “all”, etc. The term “substantially” may be varied in different technologies and be in the deviation range understood by the skilled in the art. For example, the term “substantially” may also relate to 90% of what is specified or higher, such as 95% of what is specified or higher, especially 99% of what is specified or higher, including 100% of what is specified, though the present invention is not limited thereto. Furthermore, terms such as “substantially parallel” or “substantially perpendicular” may be interpreted as not to exclude insignificant deviation from the specified arrangement and may include for example deviations of up to 10°. The word “substantially” does not exclude “completely” e.g. a composition which is “substantially free” from Y may be completely free from Y.

The term “about” may be varied in different technologies and be in the deviation range understood by the skilled in the art. The term “about” in conjunction with a specific distance or size is to be interpreted so as not to exclude insignificant deviation from the specified distance or size. For example, the term “about” may include deviations of up to 10% of what is specified, though the present invention is not limited thereto. The term “about” in relation to a numerical value x may mean x±5 or 10% of what is specified, though the present invention is not limited thereto.

Some embodiments of the disclosure are described. Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

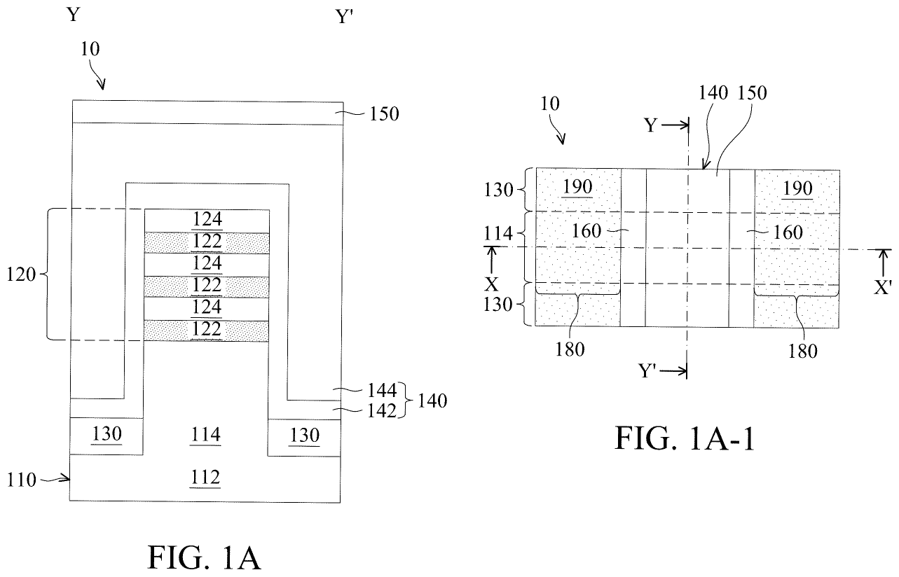

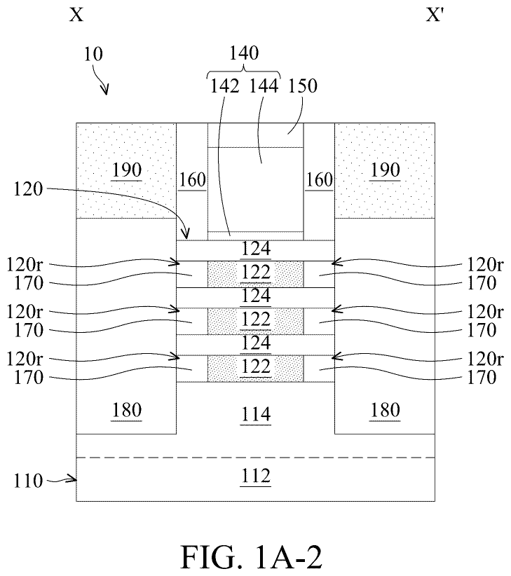

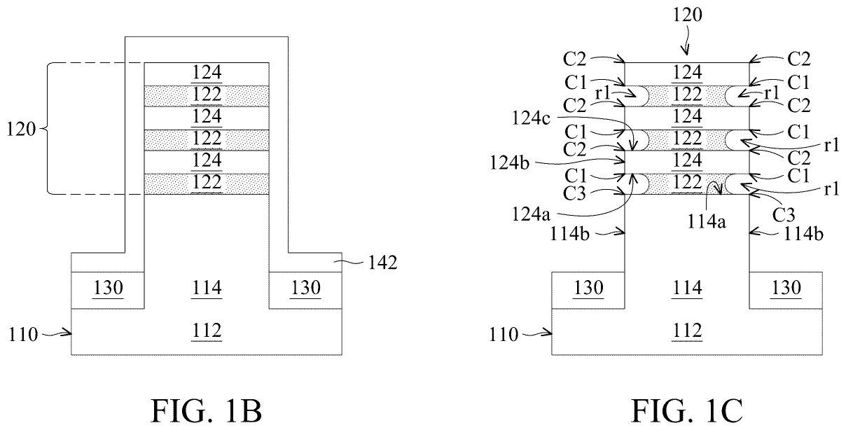

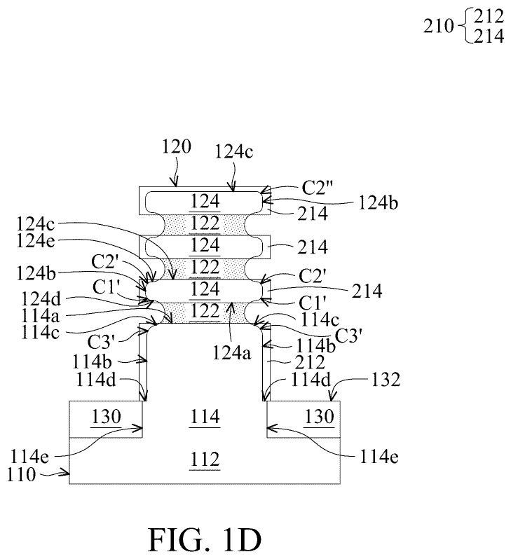

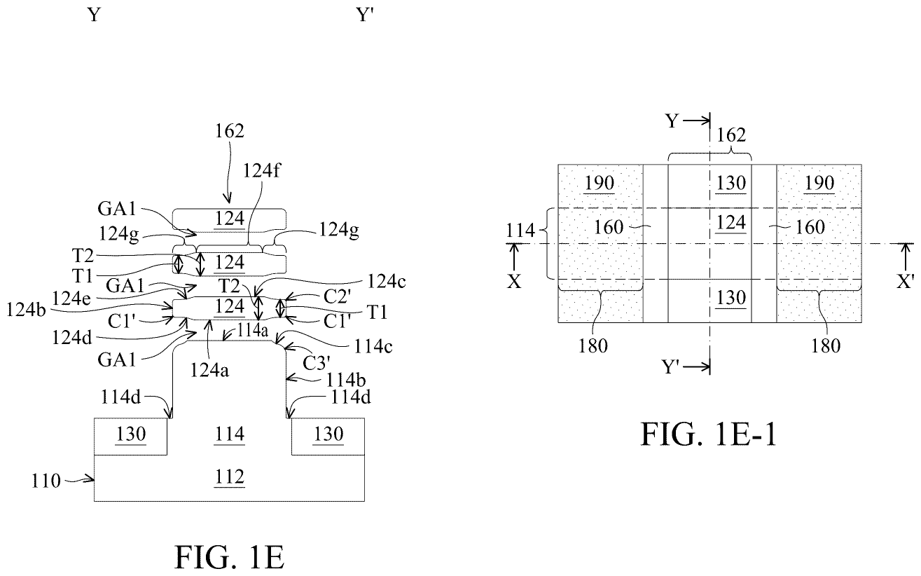

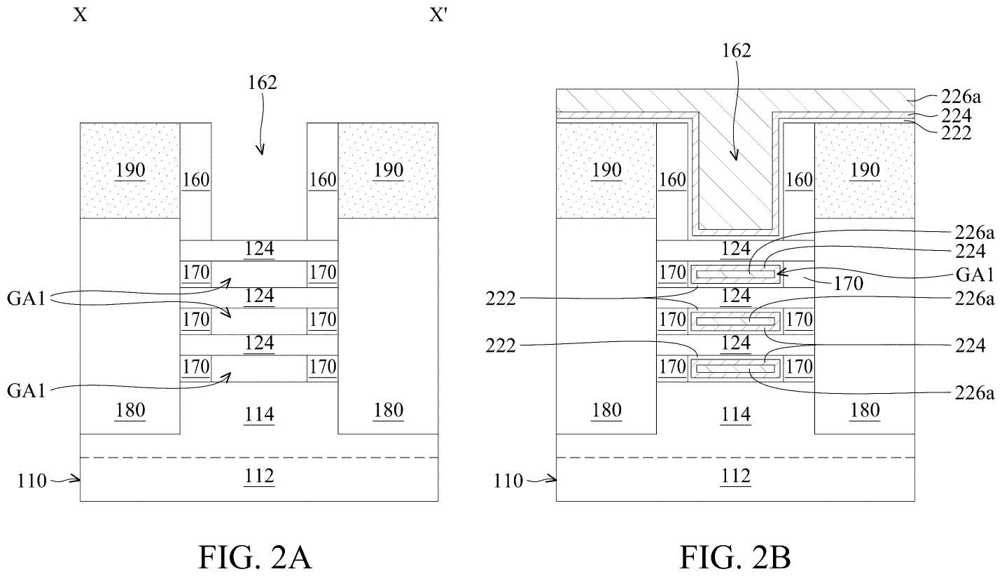

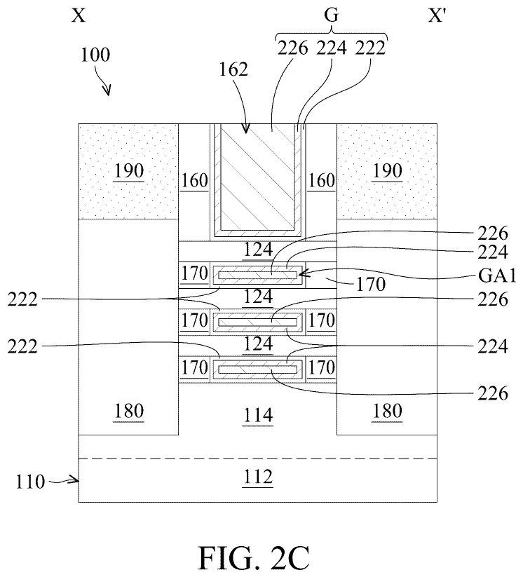

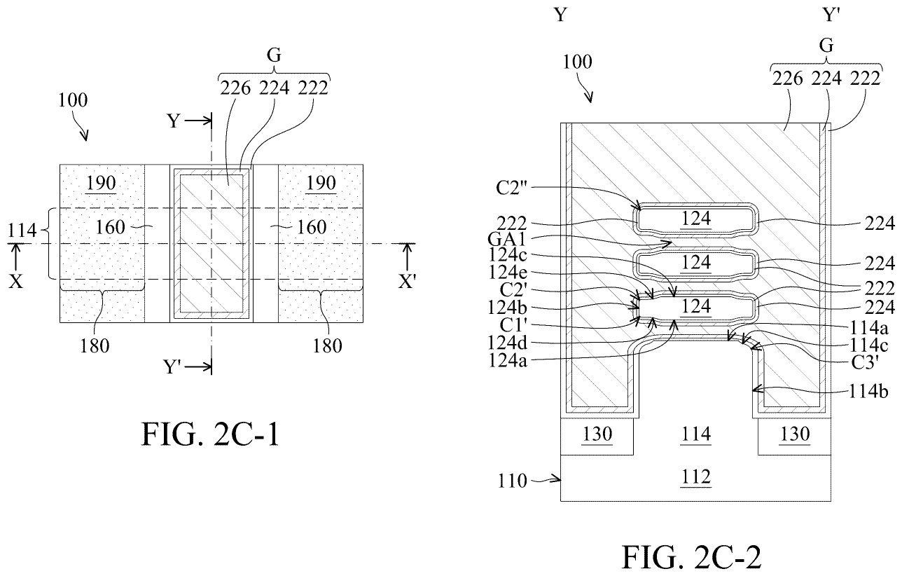

FIGS. 1A-1E are cross-sectional views of various stages of a process for forming a semiconductor device structure, in accordance with some embodiments. FIG. 1A-1 is a top view of the semiconductor device structure of FIG. 1A, in accordance with some embodiments. FIG. 1A is a cross-sectional view illustrating the semiconductor device structure along a sectional line Y-Y′ in FIG. 1A-1, in accordance with some embodiments. FIG. 1A-2 is a cross-sectional view illustrating the semiconductor device structure along a sectional line X-X′ in FIG. 1A-1, in accordance with some embodiments.

As shown in FIGS. 1A, 1A-1, and 1A-2, a substrate 110 is provided, in accordance with some embodiments. The substrate 110 has a base 112 and a fin 114 over the base 112, in accordance with some embodiments. The substrate 110 includes, for example, a semiconductor substrate. The substrate 110 includes, for example, a semiconductor wafer (such as a silicon wafer) or a portion of a semiconductor wafer.

In some embodiments, the substrate 110 is made of an elementary semiconductor material including silicon or germanium in a single crystal structure, a polycrystal structure, or an amorphous structure. In some other embodiments, the substrate 110 is made of a compound semiconductor, such as silicon carbide, gallium arsenide, gallium phosphide, indium phosphide, indium arsenide, an alloy semiconductor, such as SiGe or GaAsP, or a combination thereof. The substrate 110 may also include multi-layer semiconductors, semiconductor on insulator (SOI) (such as silicon on insulator or germanium on insulator), or a combination thereof.

In some embodiments, the substrate 110 is a device wafer that includes various device elements. In some embodiments, the various device elements are formed in and/or over the substrate 110. The device elements are not shown in figures for the purpose of simplicity and clarity. Examples of the various device elements include active devices, passive devices, other suitable elements, or a combination thereof. The active devices may include transistors or diodes (not shown) formed at a surface of the substrate 110. The passive devices include resistors, capacitors, or other suitable passive devices.

For example, the transistors may be metal oxide semiconductor field effect transistors (MOSFET), complementary metal oxide semiconductor (CMOS) transistors, bipolar junction transistors (BJT), high-voltage transistors, high-frequency transistors, p-channel and/or n-channel field effect transistors (PFETs/NFETs), etc.

Various processes, such as front-end-of-line (FEOL) semiconductor fabrication processes, are performed to form the various device elements. The FEOL semiconductor fabrication processes may include deposition, etching, implantation, photolithography, annealing, planarization, one or more other applicable processes, or a combination thereof.

In some embodiments, isolation features (not shown) are formed in the substrate 110. The isolation features are used to surround active regions and electrically isolate various device elements formed in and/or over the substrate 110 in the active regions. In some embodiments, the isolation features include shallow trench isolation (STI) features, local oxidation of silicon (LOCOS) features, other suitable isolation features, or a combination thereof.

As shown in FIGS. 1A, 1A-1, and 1A-2, a nanostructure stack 120 is formed over the fin 114, in accordance with some embodiments. The nanostructure stack 120 includes nanostructures 122 and 124, in accordance with some embodiments. The nanostructures 122 and 124 are sequentially stacked over the fin 114, in accordance with some embodiments. The nanostructures 122 and 124 include nanowires or nanosheets, in accordance with some embodiments.

As shown in FIG. 1A-2, the nanostructure stack 120 has recesses 120r, in accordance with some embodiments. The recess 120r is surrounded by the nanostructures 122 and 124 or by the nanostructures 122 and 124 and the fin 114, in accordance with some embodiments.

The nanostructures 122 are made of a same first material, in accordance with some embodiments. The first material is different from the material of the substrate 110, in accordance with some embodiments. The first material includes an oxide-containing material such as silicon oxide, in accordance with some embodiments.

The nanostructures 124 are made of a same second material, in accordance with some embodiments. The second material is different from the first material, in accordance with some embodiments. The second material is the same as the material of the substrate 110, in accordance with some embodiments. The second material includes an elementary semiconductor material including silicon or germanium in a single crystal, polycrystal, or amorphous structure, in accordance with some embodiments.

The second material includes a compound semiconductor, such as silicon carbide, gallium arsenide, gallium phosphide, indium phosphide, indium arsenide, an alloy semiconductor, such as SiGe or GaAsP, or a combination thereof, in accordance with some embodiments.

As shown in FIGS. 1A, 1A-1, and 1A-2, an isolation layer 130 is formed over the base 112, in accordance with some embodiments. The fin 114 is partially embedded in the isolation layer 130, in accordance with some embodiments. The fin 114 is surrounded by the isolation layer 130, in accordance with some embodiments.

The isolation layer 130 is made of a dielectric material such as an oxide-containing material (e.g., silicon oxide), an oxynitride-containing material (e.g., silicon oxynitride), a low-k (low dielectric constant) material, a porous dielectric material, glass, or a combination thereof, in accordance with some embodiments. The glass includes borosilicate glass (BSG), phosphoric silicate glass (PSG), borophosphosilicate glass (BPSG), fluorinated silicate glass (FSG), or a combination thereof, in accordance with some embodiments.

The isolation layer 130 is formed using a deposition process or a spin-on process and a chemical mechanical polishing process and an etching back process, in accordance with some embodiments. The deposition process includes a chemical vapor deposition (CVD) process, a high density plasma chemical vapor deposition (HDPCVD) process, a flowable chemical vapor deposition (FCVD) process, a sputtering process, or a combination thereof, in accordance with some embodiments.

As shown in FIGS. 1A, 1A-1, and 1A-2, a gate stack 140 is formed over the nanostructure stack 120, the fin 114 and the isolation layer 130, in accordance with some embodiments. The gate stack 140 is wrapped around the nanostructure stack 120 and the fin 114, in accordance with some embodiments.

The gate stack 140 includes a gate dielectric layer 142 and a gate electrode 144, in accordance with some embodiments. The gate electrode 144 is over the gate dielectric layer 142, in accordance with some embodiments. The gate dielectric layer 142 is positioned between the gate electrode 144 and the nanostructure stack 120, in accordance with some embodiments.

The gate dielectric layer 142 is also positioned between the gate electrode 144 and the fin 114, in accordance with some embodiments. The gate dielectric layer 142 is positioned between the gate electrode 144 and the isolation layer 130, in accordance with some embodiments.

The gate dielectric layer 142 is made of an oxide-containing material such as silicon oxide, in accordance with some embodiments. In some embodiments, the gate dielectric layer 142 and the nanostructures 122 are made of the same material such as an oxide-containing material (e.g., silicon oxide). The gate dielectric layer 142 is formed using a chemical vapor deposition process and an etching process, in accordance with some embodiments.

The gate electrode 144 is made of a semiconductor material such as polysilicon, in accordance with some embodiments. The gate electrode 144 is formed using a chemical vapor deposition process and an etching process, in accordance with some embodiments.

As shown in FIGS. 1A, 1A-1, and 1A-2, a mask layer 150 is formed over the gate stack 140, in accordance with some embodiments. The mask layer 150 is made of a material different from the materials of the gate stack 140, in accordance with some embodiments. The mask layer 150 is made of nitrides (e.g., silicon nitride) or oxynitride (e.g., silicon oxynitride), in accordance with some embodiments.

As shown in FIGS. 1A-1 and 1A-2, a spacer structure 160 is formed over sidewalls of the gate stack 140 and the mask layer 150, in accordance with some embodiments. The spacer structure 160 surrounds the gate stack 140 and the mask layer 150, in accordance with some embodiments. The spacer structure 160 is positioned over the nanostructure stack 120, the fin structure 114 and the isolation layer 130, in accordance with some embodiments.

The spacer structure 160 includes insulating materials, such as silicon oxide, silicon nitride, silicon oxynitride, or silicon carbide, in accordance with some embodiments. The spacer structure 160 is made of a material different from that of the gate stack 140 and the mask layer 150, in accordance with some embodiments. The formation of the spacer structure 160 includes deposition processes and an anisotropic etching process, in accordance with some embodiments.

As shown in FIG. 1A-2, an inner spacer layer 170 is formed in the recesses 120r of the nanostructure stack 120, in accordance with some embodiments. The recesses 120r are filled with the inner spacer layer 170, in accordance with some embodiments. The inner spacer layer 170 is in direct contact with sidewalls of the nanostructures 122, in accordance with some embodiments.

The inner spacer layer 170 is made of an insulating material, such as an oxide-containing material (e.g., silicon oxide), a nitride-containing material (e.g., silicon nitride), an oxynitride-containing material (e.g., silicon oxynitride), a carbide-containing material (e.g., silicon carbide), a high-k material (e.g., HfO₂, ZrO₂, HfZrO₂, or Al₂O₃), or a low-k material, in accordance with some embodiments.

The term “high-k material” means a material having a dielectric constant greater than the dielectric constant of silicon dioxide, in accordance with some embodiments. The term “low-k material” means a material having a dielectric constant less than the dielectric constant of silicon dioxide, in accordance with some embodiments.

The inner spacer layer 170 is formed using a deposition process and an etching process, in accordance with some embodiments. The deposition process includes a physical vapor deposition process, a chemical vapor deposition process, an atomic layer deposition process, or the like, in accordance with some embodiments.

As shown in FIGS. 1A-1 and 1A-2, source/drain structures 180 are formed over the fin 114, in accordance with some embodiments. The nanostructure stack 120, the inner spacer layer 170, and the gate stack 140 are between the source/drain structures 180, in accordance with some embodiments.

The source/drain structures 180 are connected to the nanostructures 124, in accordance with some embodiments. The source/drain structures 180 are in direct contact with the nanostructures 124, the inner spacer layer 170, and the fin 114, in accordance with some embodiments.

In some embodiments, the source/drain structures 180 are made of a semiconductor material (e.g., silicon germanium) with P-type dopants, such as the

Group IIIA element, in accordance with some embodiments. The Group IIIA element includes boron or another suitable material.

In some other embodiments, the source/drain structures 180 are made of a semiconductor material (e.g., silicon) with N-type dopants, such as the Group VA element, in accordance with some embodiments. The Group VA element includes phosphor (P), antimony (Sb), or another suitable Group VA material. The source/drain structures 180 are formed using an epitaxial process, in accordance with some embodiments. The source/drain structures 180 are formed using an epitaxial process, in accordance with some embodiments.

As shown in FIGS. 1A-1 and 1A-2, a dielectric layer 190 is formed over the source/drain structures 180 and the isolation layer 130, in accordance with some embodiments. The gate stack 140 and the spacer structure 160 are in the dielectric layer 190, in accordance with some embodiments.

The dielectric layer 190 includes a dielectric material such as an oxide-containing material (e.g., silicon oxide), an oxynitride-containing material (e.g., silicon oxynitride), a low-k material, a porous dielectric material, glass, or a combination thereof, in accordance with some embodiments.

The glass includes borosilicate glass (BSG), phosphoric silicate glass (PSG), borophosphosilicate glass (BPSG), fluorinated silicate glass (FSG), or a combination thereof, in accordance with some embodiments. The dielectric layer 190 is formed by a deposition process (e.g., a chemical vapor deposition process) and a planarization process (e.g., a chemical mechanical polishing process), in accordance with some embodiments.

As shown in FIG. 1B, the mask layer 150 and the gate electrode 144 are removed, in accordance with some embodiments. The removal process includes an etching process such as a wet etching process or a dry etching process, in accordance with some embodiments.

As shown in FIG. 1C, the gate dielectric layer 142 and end potions of the nanostructures 122 are removed, in accordance with some embodiments. Since the gate dielectric layer 142 and the nanostructures 122 are both made of an oxide-containing material, the gate dielectric layer 142 and the end potions of the nanostructures 122 are removed by an etching process, in accordance with some embodiments.

After the removal process is performed, recesses r1 are formed in the nanostructure stack 120, in accordance with some embodiments. The recess r1 is surrounded by the nanostructures 122 and 124 or by the nanostructures 122 and 124 and the fin 114, in accordance with some embodiments.

The nanostructure 124 has a bottom surface 124a, sidewalls 124b, and a top surface 124c, in accordance with some embodiments. The sidewalls 124b are connected between the bottom surface 124a and the top surface 124c, in accordance with some embodiments. The bottom surface 124a and the top surface 124c are substantially flat surfaces, in accordance with some embodiments.

The nanostructure 124 has corners C1 and C2, in accordance with some embodiments. Each corner C1 is between the corresponding sidewall 124b and the bottom surface 124a, in accordance with some embodiments. Each corner C2 is between the corresponding sidewall 124b and the top surface 124c, in accordance with some embodiments.

The fin 114 has a top surface 114a, sidewalls 114b, and corners C3, in accordance with some embodiments. Each corner C3 is between the corresponding sidewall 114b and the top surface 114a, in accordance with some embodiments.

As shown in FIGS. 1C and 1D, an oxidation process is performed on the fin 114 and the nanostructures 124 to form an oxide layer 210 on the fin 114 and the nanostructures 124, in accordance with some embodiments. The oxide layer 210 has portions 212 and 214, in accordance with some embodiments.

The portions 212 and 214 are over the fin 114 and the nanostructures 124 respectively, in accordance with some embodiments. The portions 212 and 214 are spaced apart from each other, in accordance with some embodiments.

The portion 212 is made of an oxide of the material of the fin 114, in accordance with some embodiments. The portions 214 are made of an oxide of the material of the nanostructures 124, in accordance with some embodiments. Therefore, the formation of the oxide layer 210 consumes surface portions of the nanostructures 124 and the fin 114, in accordance with some embodiments.

Since the oxidation rate of the corners C1, C2, and C3 is greater than that of the top surface 124c, the sidewalls 124b, and the bottom surface 124a of the nanostructures 124 and the top surface 114a and the sidewalls 114b of the fin 114, the oxidation process rounds the corners C1, C2, and C3, in accordance with some embodiments.

The corners C1 become rounded corners C1′ after the oxidation process is performed, in accordance with some embodiments. The corners C2 become rounded corners C2′ or C2″ after the oxidation process is performed, in accordance with some embodiments. The corners C3 become rounded corners C3′ after the oxidation process is performed, in accordance with some embodiments.

Since the formation of the oxide layer 210 consumes surface portions of the nanostructures 124 and the fin 114, the nanostructure 124 has concave lower surfaces 124d and concave upper surfaces 124e, and the fin 114 has concave upper surfaces 114c after the oxidation process is performed, in accordance with some embodiments.

Each concave lower surface 124d is connected between the bottom surface 124a and the corresponding sidewall 124b, in accordance with some embodiments. Each rounded corner C1′ is between the corresponding sidewall 124b and the corresponding concave lower surface 124d, in accordance with some embodiments.

Each concave upper surface 124e is connected between the top surface 124c and the corresponding sidewall 124b, in accordance with some embodiments. Each rounded corner C2′ is between the corresponding sidewall 124b and the corresponding concave upper surface 124e, in accordance with some embodiments. The topmost one of the nanostructures 124 has rounded corners C2″, in accordance with some embodiments. Each rounded corner C2″ is between the corresponding sidewall 124b and the top surface 124c, in accordance with some embodiments.

Each concave upper surface 114c is connected between the top surface 114a and the corresponding sidewall 114b of the fin 114, in accordance with some embodiments. Each rounded corner C3′ is between the corresponding sidewall 114b and the corresponding concave upper surface 114c, in accordance with some embodiments.

The concave upper surface 114c of the fin 114 is under the corresponding concave lower surface 124d of the nanostructure 124, in accordance with some embodiments. The concave lower surface 124d of the nanostructure 124 is between the corresponding concave upper surface 124e of the nanostructure 124 and the corresponding concave upper surface 114c of the fin 114, in accordance with some embodiments. The sidewall 114b of the fin 114 is under the sidewall 124b of the nanostructure 124, in accordance with some embodiments.

Since the formation of the portion 212 of the oxide layer 210 consumes the surface portions of the fin 114, the fin 114 has an upper surface 114d connected between the sidewall 114b and a lower sidewall 114e of the fin 114 after the oxidation process is performed, in accordance with some embodiments.

The upper surface 114d is substantially level with a top surface 132 of the isolation layer 130, in accordance with some embodiments. The sidewall 114b is misaligned with the lower sidewall 114e of the fin 114, in accordance with some embodiments.

The average film thickness of the oxide layer 210 ranges from about 5 Å to about 3 nm, in accordance with some embodiments. If the average film thickness of the oxide layer 210 is less than 5 Å, the corners C1, C2, and C3 may not be sufficiently rounded. If the average film thickness of the oxide layer 210 is greater than 3 nm, the oxidation process may consume too much of the nanostructures 124, which may increase the resistance of the nanostructures 124.

The oxidation process includes a chemical oxidation process, in accordance with some embodiments. The chemical oxidation process includes dipping the semiconductor device structure of FIG. 1C into an oxidation solution, in accordance with some embodiments. The oxidation solution includes liquid ozone (O₃) or NH₄OH and hydrogen peroxide (H₂O₂), in accordance with some embodiments.

FIG. 1E-1 is a top view of the semiconductor device structure of FIG. 1E, in accordance with some embodiments. FIG. 1E is a cross-sectional view illustrating the semiconductor device structure along a sectional line Y-Y′ in FIG. 1E-1, in accordance with some embodiments.

FIG. 2A is a cross-sectional view illustrating the semiconductor device structure along a sectional line X-X′ in FIG. 1E-1, in accordance with some embodiments. As shown in FIGS. 1E, 1E-1 and 2A, the oxide layer 210 and the nanostructures 122 are removed, in accordance with some embodiments.

As shown in FIGS. 1E and 2A, the nanostructures 124 and the fin 114 are spaced apart from each other by gaps GA1, in accordance with some embodiments. As shown in FIGS. 1E, 1E-1 and 2A, the spacer structure 160 has a trench 162 exposing the nanostructures 124, in accordance with some embodiments.

As shown in FIG. 1E, the nanostructure 124 has a central portion 124f and a peripheral portion 124g, in accordance with some embodiments. The central portion 124f is the portion of the nanostructure 124 between the bottom surface 124a and the top surfaces 124c, in accordance with some embodiments. The peripheral portion 124g is the portion of the nanostructure 124 between the concave lower surfaces 124d and the concave upper surfaces 124e, in accordance with some embodiments.

The central portion 124f is thicker than the peripheral portion 124g, in accordance with some embodiments. A ratio of the thickness T1 of the peripheral portion 124g to the thickness T2 of the central portion 124f ranges from about 0.2 to about 0.99, in accordance with some embodiments.

The removal process includes an etching process such as a wet etching process or a dry etching process, in accordance with some embodiments. The etchant of the wet etching process includes dilute HF, in accordance with some embodiments. The etchant of the dry etching process includes NH₃ and HF, in accordance with some embodiments.

FIGS. 2A-2C are cross-sectional views of various stages of a process for forming a semiconductor device structure, in accordance with some embodiments. As shown in FIG. 2B, a gate dielectric layer 222 is formed over the nanostructures 124, the fin 114, the spacer structure 160, the inner spacer layer 170 and the dielectric layer 190, in accordance with some embodiments.

The gate dielectric layer 222 conformally covers the nanostructures 124, the fin 114, the spacer structure 160, the inner spacer layer 170 and the dielectric layer 190, in accordance with some embodiments. The gate dielectric layer 222 surrounds the nanostructures 124 and the fin 114, in accordance with some embodiments.

The gate dielectric layer 222 is made of a high-K material, such as HfO₂, La₂O₃, CaO, ZrO₂, HfZrO₂, or Al₂O₃, in accordance with some embodiments. The gate dielectric layer 222 is formed using an atomic layer deposition process or another suitable process.

As shown in FIG. 2B, a work function metal layer 224 is conformally formed over the gate dielectric layer 222, in accordance with some embodiments. The work function metal layer 224 provides a desired work function for transistors to enhance device performance including improved threshold voltage.

In the embodiments of forming an NMOS transistor, the work function metal layer 224 can be a metal capable of providing a work function value suitable for the device, such as equal to or less than about 4.5 eV. The work function metal layer 224 is made of metal, metal carbide, metal nitride, or a combination thereof, in accordance with some embodiments. For example, the work function metal layer 224 is made of tantalum, hafnium carbide, zirconium carbide, tantalum nitride, or a combination thereof.

In the embodiments of forming a PMOS transistor, the work function metal layer 224 can be a metal capable of providing a work function value suitable for the device, such as equal to or greater than about 4.8 eV. The work function metal layer 224 is made of metal, metal carbide, metal nitride, another suitable material, or a combination thereof, in accordance with some embodiments. For example, the work function metal layer 224 is made of titanium, titanium nitride, another suitable material, or a combination thereof.

The work function metal layer 224 is formed using a deposition process, a photolithography process, and an etching process, in accordance with some embodiments. The deposition process includes a physical vapor deposition process, a chemical vapor deposition process, an atomic layer deposition process, or a combination thereof, in accordance with some embodiments.

As shown in FIG. 2B, a gate electrode layer 226a is formed over the work function metal layer 224, in accordance with some embodiments. The trench 162 of the spacer structure 160 and the gaps GA1 between the fin 114 and the nanostructures 124 are completely filled with the gate electrode layer 226a, in accordance with some embodiments.

The gate electrode layer 226a is made of metal, metal nitride, or metal carbide, in accordance with some embodiments. The gate electrode layer 226a is made of tungsten, titanium nitride, tantalum nitride, titanium aluminide, titanium carbide, or a combination thereof, in accordance with some embodiments.

The gate electrode layer 226a is formed using an atomic layer deposition process, a chemical vapor deposition process, or a physical vapor deposition process, in accordance with some embodiments.

FIG. 2C-1 is a top view of the semiconductor device structure of FIG. 2C, in accordance with some embodiments. FIG. 2C is a cross-sectional view illustrating the semiconductor device structure along a sectional line X-X′ in FIG. 2C-1, in accordance with some embodiments. FIG. 2C-2 is a cross-sectional view illustrating the semiconductor device structure along a sectional line Y-Y′ in FIG. 2C-1, in accordance with some embodiments.

As shown in FIGS. 2B, 2C, 2C-1, and 2C-2, the gate dielectric layer 222, the work function metal layer 224, and the gate electrode layer 226a outside of the trench 162 and the gaps GA1 are removed, in accordance with some embodiments.

The gate electrode layer 226a remaining in the trench 162 and the gaps GA1 forms a gate electrode 226, in accordance with some embodiments. The gate electrode 226 surrounds the nanostructures 124, in accordance with some embodiments. The gate electrode 226, the work function metal layer 224, and the gate dielectric layer 222 together form a gate stack G, in accordance with some embodiments. The gate stack G is wrapped around the nanostructures 124 and the fin 114, in accordance with some embodiments.

The removal process includes a planarization process such as a chemical mechanical polishing process, in accordance with some embodiments.

In this step, a semiconductor device structure 100 is substantially formed, in accordance with some embodiments. The semiconductor device structure 100 includes an NMOS transistor or a PMOS transistor, in accordance with some embodiments. The semiconductor device structure 100 includes a gate-all-around (GAA) transistor, in accordance with some embodiments.

As shown in FIG. 2C-2, the gate dielectric layer 222 conformally covers the bottom surfaces 124a, the sidewalls 124b, the top surfaces 124c, the concave lower surfaces 124d, the concave upper surfaces 124e, and the rounded corners C1′, C2′ and C2″ of the nanostructures 124 and the top surface 114a, the sidewalls 114b, the concave upper surfaces 114c, and the rounded corners C3′ of the fin 114, in accordance with some embodiments.

Since the corners C1, C2, and C3 in FIG. 1C are rounded to form the rounded corners C1′, C2′, C2″ and C3′, the coverage of the gate dielectric layer 222 on the nanostructures 124 and the fin 114 is improved, which improves the yield of the gate dielectric layer 222 and the reliability of the semiconductor device structure 100, in accordance with some embodiments.

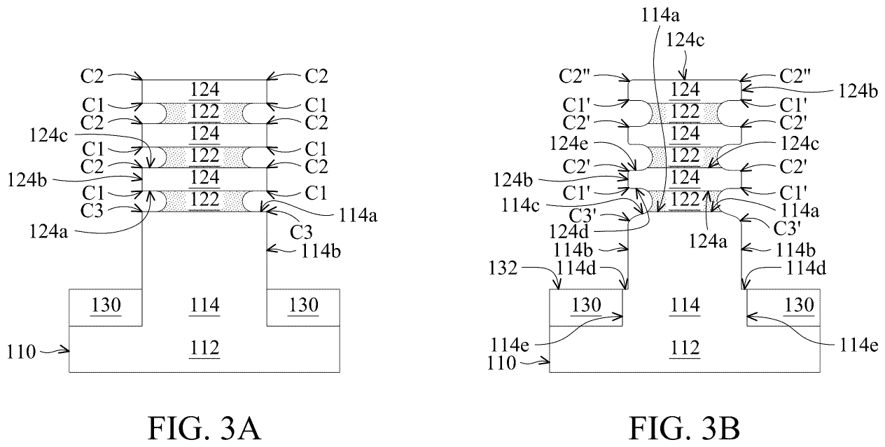

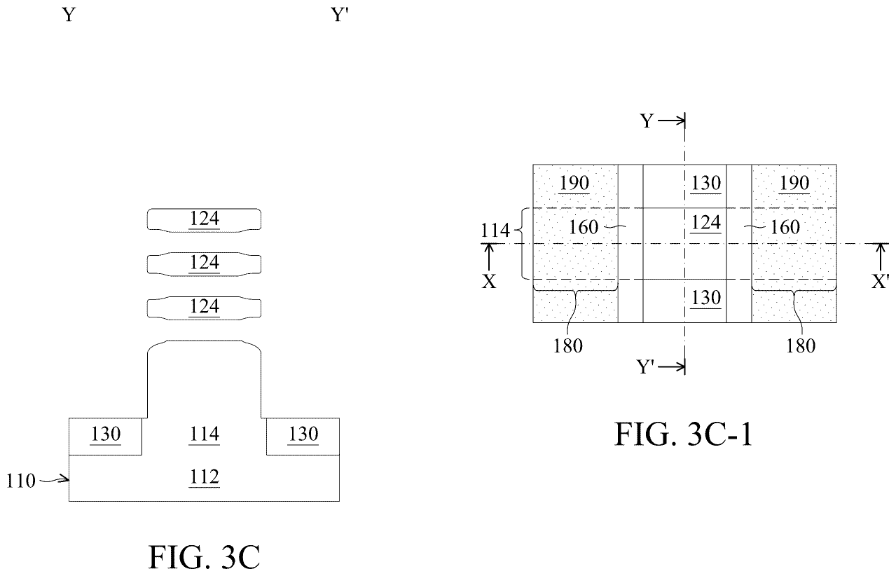

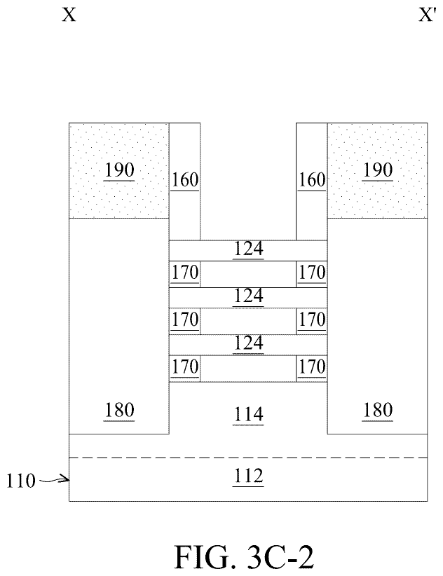

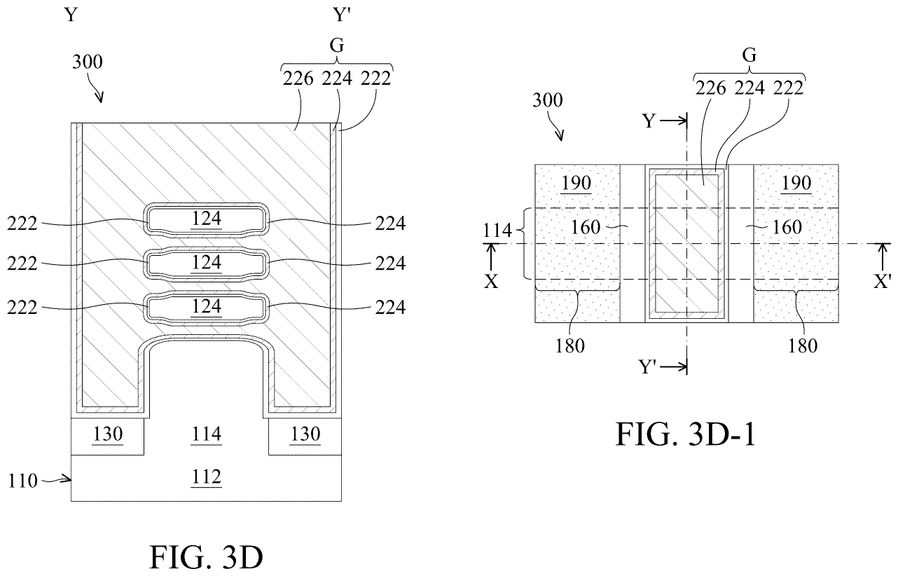

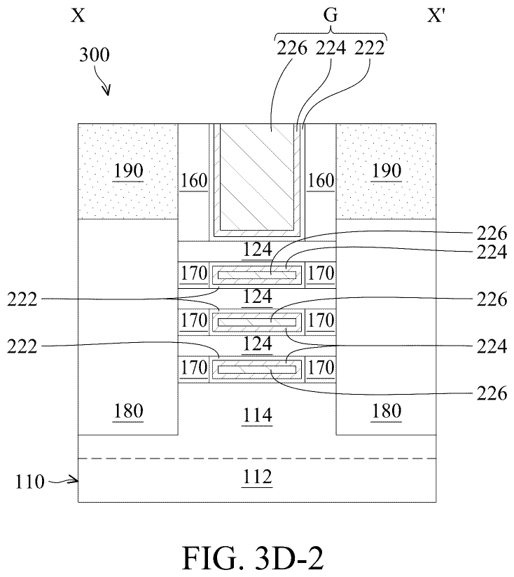

FIGS. 3A-3D are cross-sectional views of various stages of a process for forming a semiconductor device structure, in accordance with some embodiments. As shown in FIG. 3A, the step of FIG. 1C is performed to remove the gate dielectric layer 142 and end potions of the nanostructures 122, in accordance with some embodiments.

As shown in FIGS. 3A and 3B, an etching process is performed on the nanostructures 124 and the fin 114 to remove surface portions of the nanostructures 124 and the fin 114, in accordance with some embodiments.

Since the etching rate of the corners C1, C2, and C3 is greater than that of the top surfaces 124c, the sidewalls 124b, and the bottom surface 124a of the nanostructures 124 and the top surface 114a and the sidewalls 114b of the fin 114, the etching process rounds the corners C1, C2, and C3, in accordance with some embodiments.

The corners C1 become rounded corners C1′ after the etching process is performed, in accordance with some embodiments. The corners C2 become rounded corners C2′ or C2″ after the etching process is performed, in accordance with some embodiments. The corners C3 become rounded corners C3′ after the etching process is performed, in accordance with some embodiments. The upper surface 114d of the fin 114 is formed after the etching process is performed, in accordance with some embodiments.

After the etching process is performed, the nanostructure 124 has concave lower surfaces 124d and concave upper surfaces 124e, and the fin 114 has concave upper surfaces 114c, in accordance with some embodiments. Each concave lower surface 124d is connected between the bottom surface 124a and the corresponding sidewall 124b, in accordance with some embodiments. Each rounded corner C1′ is between the corresponding sidewall 124b and the corresponding concave lower surface 124d, in accordance with some embodiments.

Each concave upper surface 124e is connected between the top surface 124c and the corresponding sidewall 124b, in accordance with some embodiments. Each rounded corner C2′ is between the corresponding sidewall 124b and the corresponding concave upper surface 124e, in accordance with some embodiments. The topmost one of the nanostructures 124 has rounded corners C2″, in accordance with some embodiments. Each rounded corner C2″ is between the corresponding sidewall 124b and the top surface 124c, in accordance with some embodiments.

Each concave upper surface 114c is connected between the top surface 114a and the corresponding sidewall 114b of the fin 114, in accordance with some embodiments. Each rounded corner C3′ is between the corresponding sidewall 114b and the corresponding concave upper surface 114c, in accordance with some embodiments.

The etching process includes an isotropic etching process, in accordance with some embodiments. The etching process includes a wet etching process or a dry etching process, in accordance with some embodiments. The etchant of the wet etching process includes NH₄OH, in accordance with some embodiments. The etchant of the dry etching process includes NH₃ and F₂, in accordance with some embodiments.

FIG. 3C-1 is a top view of the semiconductor device structure of FIG. 3C, in accordance with some embodiments. FIG. 3C is a cross-sectional view illustrating the semiconductor device structure along a sectional line Y-Y′ in FIG. 3C-1, in accordance with some embodiments.

FIG. 3C-2 is a cross-sectional view illustrating the semiconductor device structure along a sectional line X-X′ in FIG. 3C-1, in accordance with some embodiments. As shown in FIGS. 3C, 3C-1, and 3C-2, the step of FIG. 1E is performed to remove the nanostructures 122, in accordance with some embodiments.

FIG. 3D-1 is a top view of the semiconductor device structure of FIG. 3D, in accordance with some embodiments. FIG. 3D is a cross-sectional view illustrating the semiconductor device structure along a sectional line Y-Y′ in FIG. 3D-1, in accordance with some embodiments.

FIG. 3D-2 is a cross-sectional view illustrating the semiconductor device structure along a sectional line X-X′ in FIG. 3D-1, in accordance with some embodiments. As shown in FIGS. 3D, 3D-1, and 3D-2, the steps of FIGS. 2B and 2C are performed to form the gate stack G, in accordance with some embodiments. In this step, a semiconductor device structure 300 is substantially formed, in accordance with some embodiments.

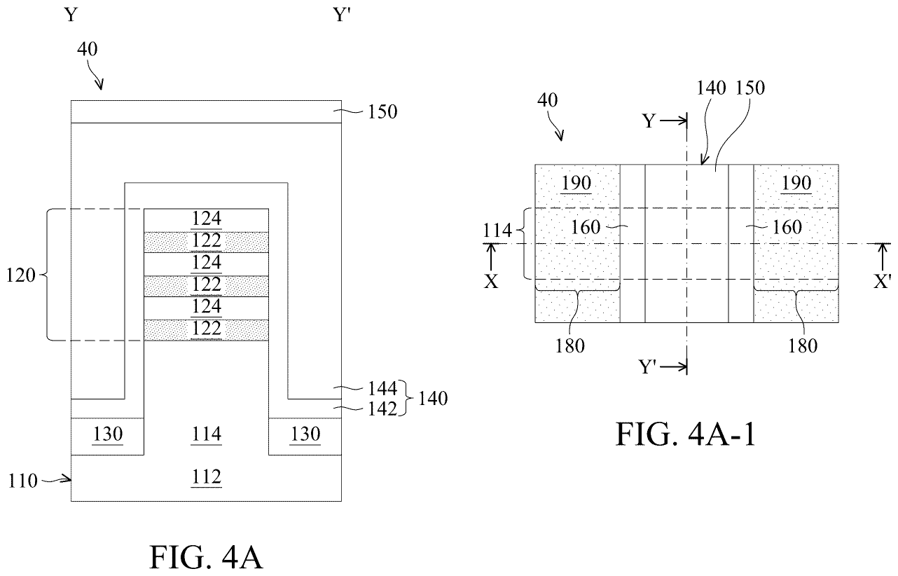

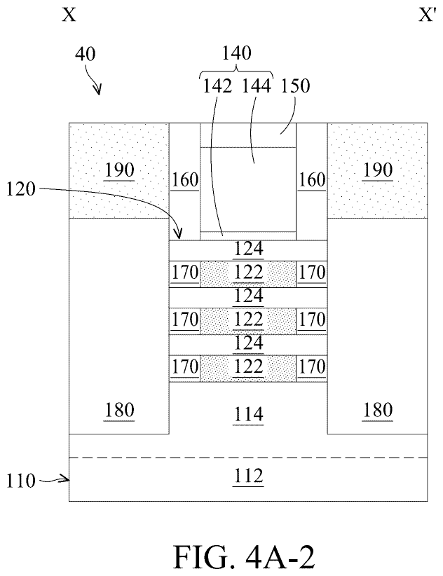

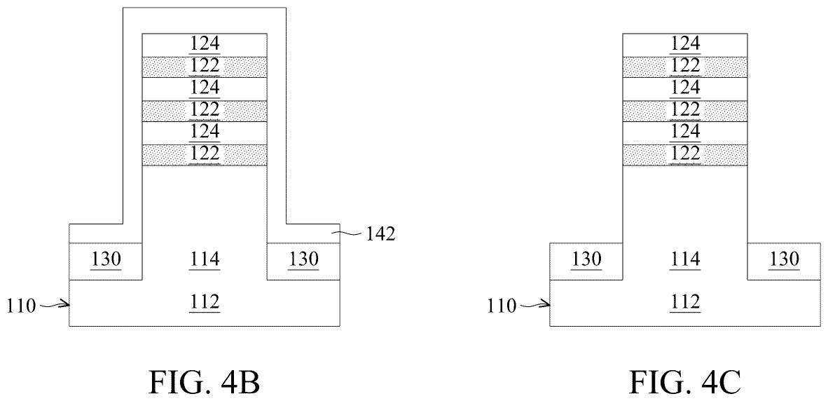

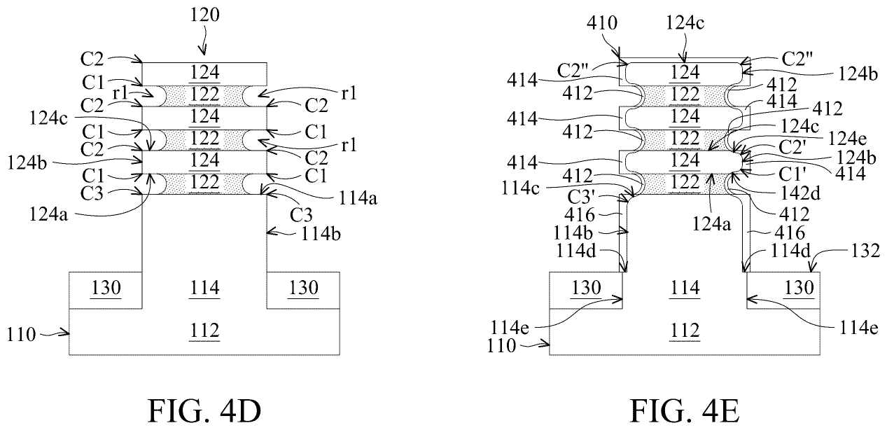

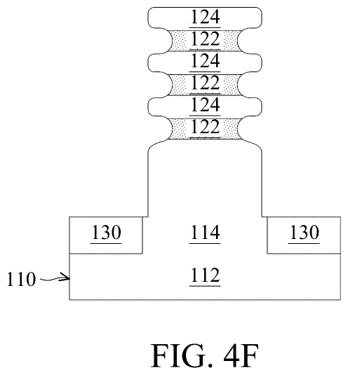

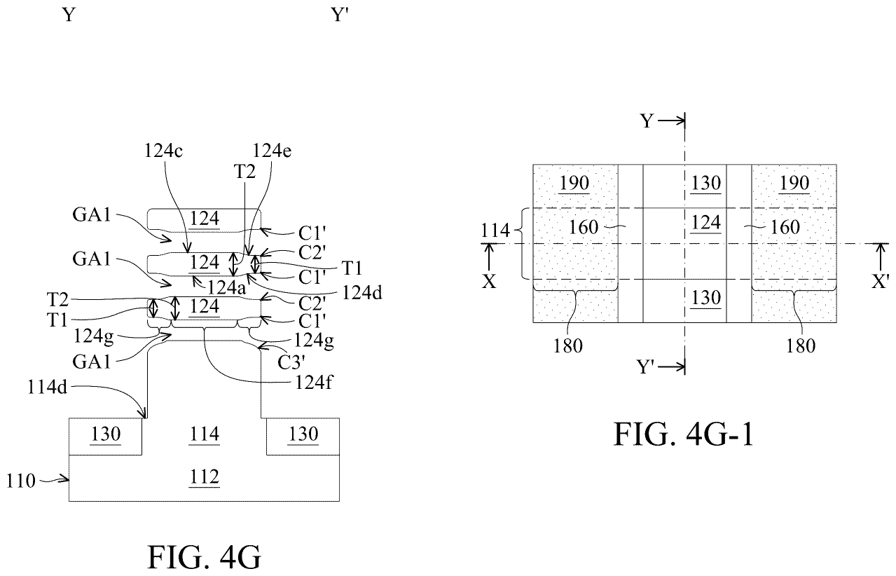

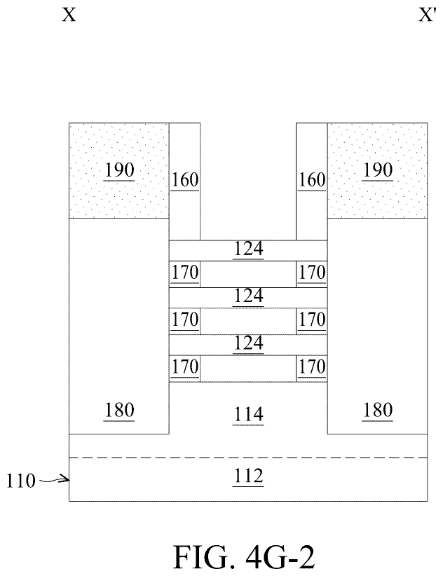

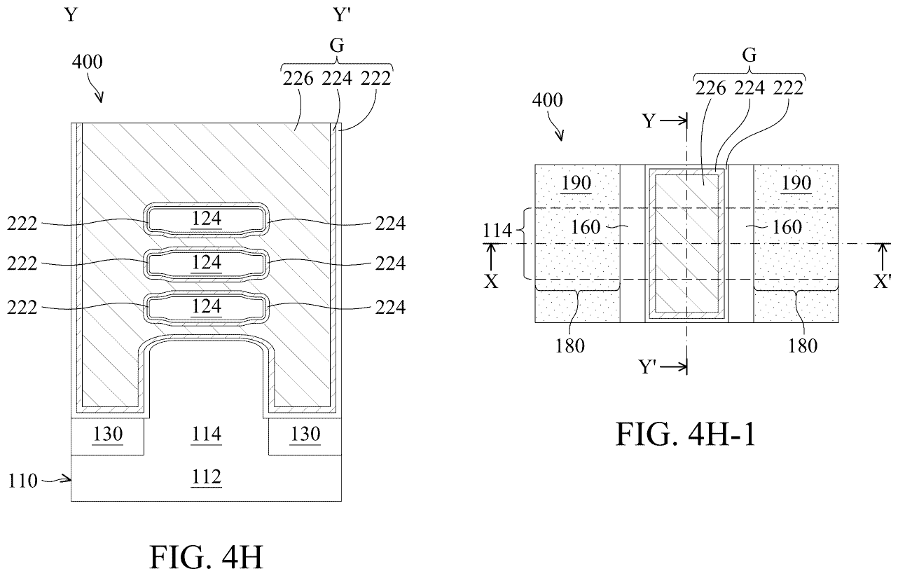

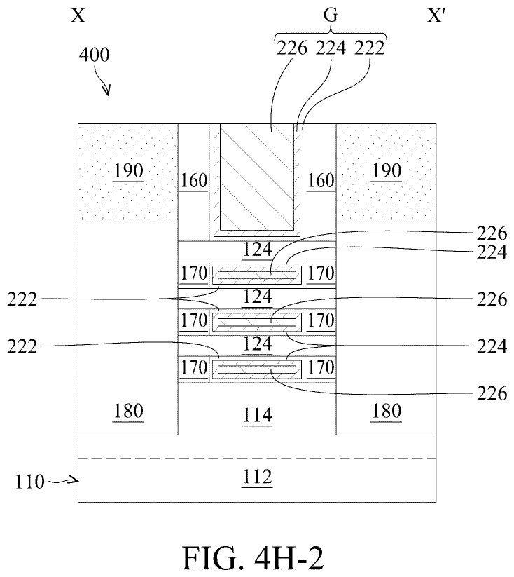

FIGS. 4A-4H are cross-sectional views of various stages of a process for forming a semiconductor device structure, in accordance with some embodiments. FIG. 4A-1 is a top view of the semiconductor device structure of FIG. 4A, in accordance with some embodiments.

FIG. 4A is a cross-sectional view illustrating the semiconductor device structure along a sectional line Y-Y′ in FIG. 4A-1, in accordance with some embodiments. FIG. 4A-2 is a cross-sectional view illustrating the semiconductor device structure along a sectional line X-X′ in FIG. 4A-1, in accordance with some embodiments.

As shown in FIGS. 4A, 4A-1, and 4A-2, the semiconductor device structure 40 of FIGS. 4A, 4A-1, and 4A-2 is similar to the semiconductor device structure 10 of FIGS. 1A, 1A-1, and 1A-2, except that the nanostructures 122 and the gate dielectric layer 142 are made of different materials, in accordance with some embodiments.

The nanostructures 122 is made of a compound semiconductor, such as silicon carbide, gallium arsenide, gallium phosphide, indium phosphide, indium arsenide, an alloy semiconductor, such as SiGe or GaAsP, or a combination thereof, in accordance with some embodiments. The gate dielectric layer 142 is made of an oxide-containing material such as silicon oxide, in accordance with some embodiments.

As shown in FIG. 4B, the step of FIG. 1B is performed to remove the mask layer 150 and the gate electrode 144, in accordance with some embodiments. The removal process includes an etching process such as a wet etching process or a dry etching process, in accordance with some embodiments.

As shown in FIG. 4C, the gate dielectric layer 142 is removed, in accordance with some embodiments. The removal process includes an etching process such as a wet etching process or a dry etching process, in accordance with some embodiments.

As shown in FIG. 4D, end potions of the nanostructures 122 are removed, in accordance with some embodiments. After the removal process is performed, recesses r1 are formed in the nanostructure stack 120, in accordance with some embodiments. The recess r1 is surrounded by the nanostructures 122 and 124 or by the nanostructures 122 and 124 and the fin 114, in accordance with some embodiments.

The nanostructure 124 has a bottom surface 124a, sidewalls 124b, and a top surface 124c, in accordance with some embodiments. The sidewalls 124b are connected between the bottom surface 124a and the top surface 124c, in accordance with some embodiments.

The nanostructure 124 has corners C1 and C2, in accordance with some embodiments. Each corner C1 is between the corresponding sidewall 124b and the bottom surface 124a, in accordance with some embodiments. Each corner C2 is between the corresponding sidewall 124b and the top surface 124c, in accordance with some embodiments.

The fin 114 has a top surface 114a, sidewalls 114b, and corners C3, in

accordance with some embodiments. Each corner C3 is between the corresponding sidewall 114b and the top surface 114a, in accordance with some embodiments. The removal process includes an etching process such as a wet etching process or a dry etching process, in accordance with some embodiments.

As shown in FIGS. 4D and 4E, an oxidation process is performed on the fin 114 and the nanostructures 122 and 124 to form an oxide layer 410 on the fin 114 and the nanostructures 122 and 124, in accordance with some embodiments. The oxide layer 410 has portions 412, 414, and 416, in accordance with some embodiments. The portions 412 are connected between the portions 414 and 416, in accordance with some embodiments.

The portions 412 are made of an oxide of the material of the nanostructures 122, in accordance with some embodiments. The portions 414 are made of an oxide of the material of the nanostructures 124, in accordance with some embodiments. The portions 416 are made of an oxide of the material of the fin 114, in accordance with some embodiments. Therefore, the formation of the oxide layer 410 consumes surface portions of the nanostructures 122 and 124 and the fin 114, in accordance with some embodiments.

Since the oxidation rate of the corners C1, C2, and C3 is greater than that of the top surface 124c, the sidewalls 124b, and the bottom surface 124a of the nanostructures 124 and the top surface 114a and the sidewalls 114b of the fin 114, the oxidation process rounds the corners C1, C2, and C3, in accordance with some embodiments.

The corners C1 become rounded corners C1′ after the oxidation process is performed, in accordance with some embodiments. The corners C2 become rounded corners C2′ or C2″ after the oxidation process is performed, in accordance with some embodiments. The corners C3 become rounded corners C3′ after the oxidation process is performed, in accordance with some embodiments.

Since the formation of the oxide layer 410 consumes surface portions of the nanostructures 124 and the fin 114, the nanostructure 124 has concave lower surfaces 124d and concave upper surfaces 124e, and the fin 114 has concave upper surfaces 114c after the oxidation process is performed, in accordance with some embodiments.

Each concave lower surface 124d is connected between the bottom surface 124a and the corresponding sidewall 124b, in accordance with some embodiments. Each rounded corner C1′ is between the corresponding sidewall 124b and the corresponding concave lower surface 124d, in accordance with some embodiments.

Each concave upper surface 124e is connected between the top surface 124c and the corresponding sidewall 124b, in accordance with some embodiments. Each rounded corner C2′ is between the corresponding sidewall 124b and the corresponding concave upper surface 124e, in accordance with some embodiments. The topmost one of the nanostructures 124 has rounded corners C2″, in accordance with some embodiments. Each rounded corner C2″ is between the corresponding sidewall 124b and the top surface 124c, in accordance with some embodiments.

Each concave upper surface 114c is connected between the top surface 114a and the corresponding sidewall 114b of the fin 114, in accordance with some embodiments. Each rounded corner C3′ is between the corresponding sidewall 114b and the corresponding concave upper surface 114c, in accordance with some embodiments.

The concave upper surface 114c of the fin 114 is under the corresponding concave lower surface 124d of the nanostructure 124, in accordance with some embodiments. The concave lower surface 124d of the nanostructure 124 is between the corresponding concave upper surface 124e of the nanostructure 124 and the corresponding concave upper surface 114c of the fin 114, in accordance with some embodiments. The sidewall 114b of the fin 114 is under the sidewall 124b of the nanostructure 124, in accordance with some embodiments.

Since the formation of the portion 416 of the oxide layer 410 consumes the surface portions of the fin 114, the fin 114 has an upper surface 114d connected between the sidewall 114b and a lower sidewall 114e of the fin 114 after the oxidation process is performed, in accordance with some embodiments.

The upper surface 114d is substantially level with a top surface 132 of the isolation layer 130, in accordance with some embodiments. The sidewall 114b is misaligned with the lower sidewall 114e of the fin 114, in accordance with some embodiments.

The average film thickness of the oxide layer 410 ranges from about 5 Å to about 3 nm, in accordance with some embodiments. If the average film thickness of the oxide layer 410 is less than 5 Å, the corners C1, C2, and C3 may not be sufficiently rounded. If the average film thickness of the oxide layer 410 is greater than 3 nm, the oxidation process may consume too much of the nanostructures 124, which may increase the resistance of the nanostructures 124.

The oxidation process includes a chemical oxidation process, in accordance with some embodiments. The chemical oxidation process includes dipping the semiconductor device structure of FIG. 4D into an oxidation solution, in accordance with some embodiments. The oxidation solution includes liquid ozone (O₃) or NHOH and hydrogen peroxide (H₂O₂), in accordance with some embodiments.

As shown in FIG. 4F, the oxide layer 410 is removed, in accordance with some embodiments. The removal process includes an etching process such as a wet etching process or a dry etching process, in accordance with some embodiments. The etchant of the wet etching process includes dilute HF, in accordance with some embodiments. The etchant of the dry etching process includes NH₃ and HF, in accordance with some embodiments.

FIG. 4G-1 is a top view of the semiconductor device structure of FIG. 4G, in accordance with some embodiments. FIG. 4G is a cross-sectional view illustrating the semiconductor device structure along a sectional line Y-Y′ in FIG. 4G-1, in accordance with some embodiments. FIG. 4G-2 is a cross-sectional view illustrating the semiconductor device structure along a sectional line X-X′ in FIG. 4G-1, in accordance with some embodiments.

As shown in FIGS. 4G, 4G-1, and 4G-2, the nanostructures 122 are removed, in accordance with some embodiments. The removal process includes an etching process such as a dry etching process, in accordance with some embodiments. The etchant of the dry etching process includes F₂ and HF, in accordance with some embodiments.

As shown in FIGS. 4G, the nanostructure 124 has a central portion 124f and a peripheral portion 124g, in accordance with some embodiments. The central portion 124f is the portion of the nanostructure 124 between the bottom surface 124a and the top surfaces 124c, in accordance with some embodiments. The peripheral portion 124g is the portion of the nanostructure 124 between the concave lower surfaces 124d and the concave upper surfaces 124e, in accordance with some embodiments.

The central portion 124f is thicker than the peripheral portion 124g, in accordance with some embodiments. A ratio of the thickness T1 of the peripheral portion 124g to the thickness T2 of the central portion 124f ranges from about 0.2 to about 0.99, in accordance with some embodiments.

FIG. 4H-1 is a top view of the semiconductor device structure of FIG. 4H, in accordance with some embodiments. FIG. 4H is a cross-sectional view illustrating the semiconductor device structure along a sectional line Y-Y′ in FIG. 4H-1, in accordance with some embodiments. FIG. 4H-2 is a cross-sectional view illustrating the semiconductor device structure along a sectional line X-X′ in FIG. 4H-1, in accordance with some embodiments.

As shown in FIGS. 4H, 4H-1, and 4H-2, the steps of FIGS. 2B and 2C are performed to form the gate stack G, in accordance with some embodiments. In this step, a semiconductor device structure 400 is substantially formed, in accordance with some embodiments.

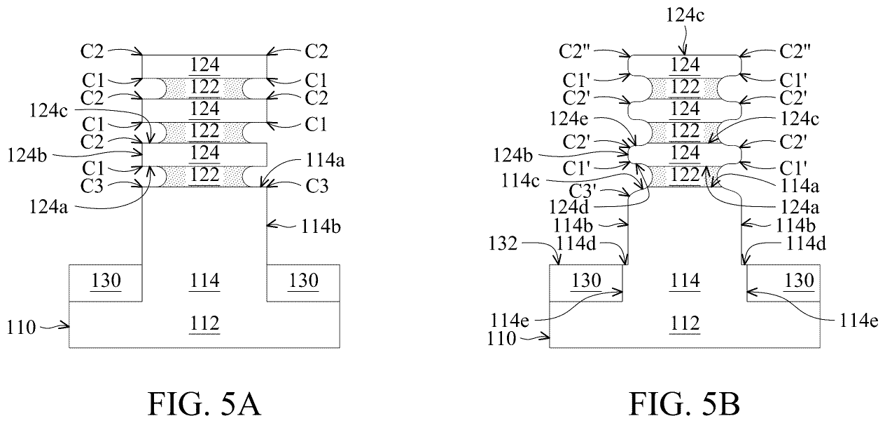

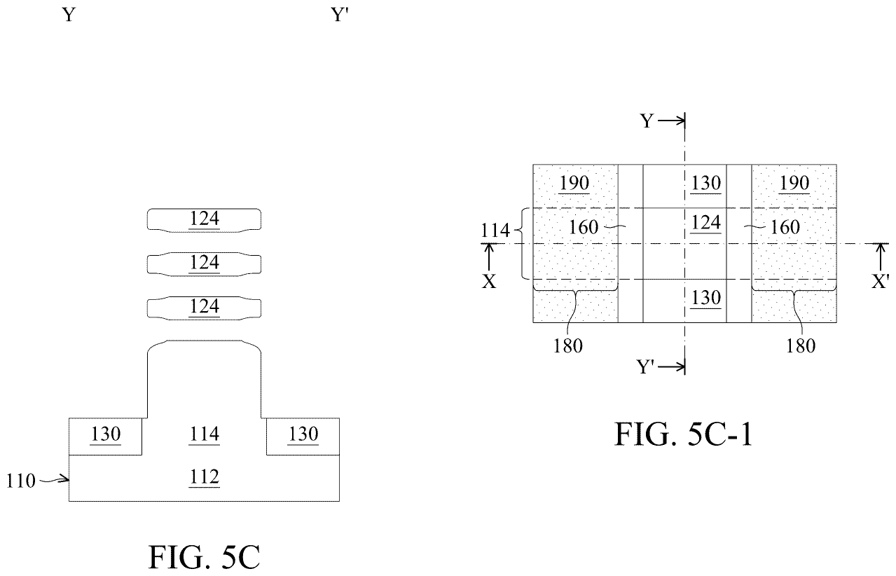

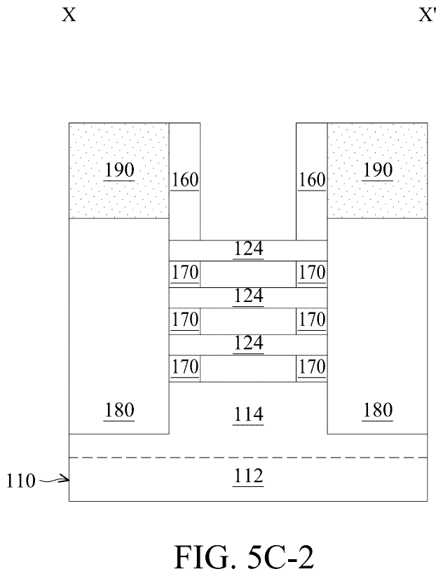

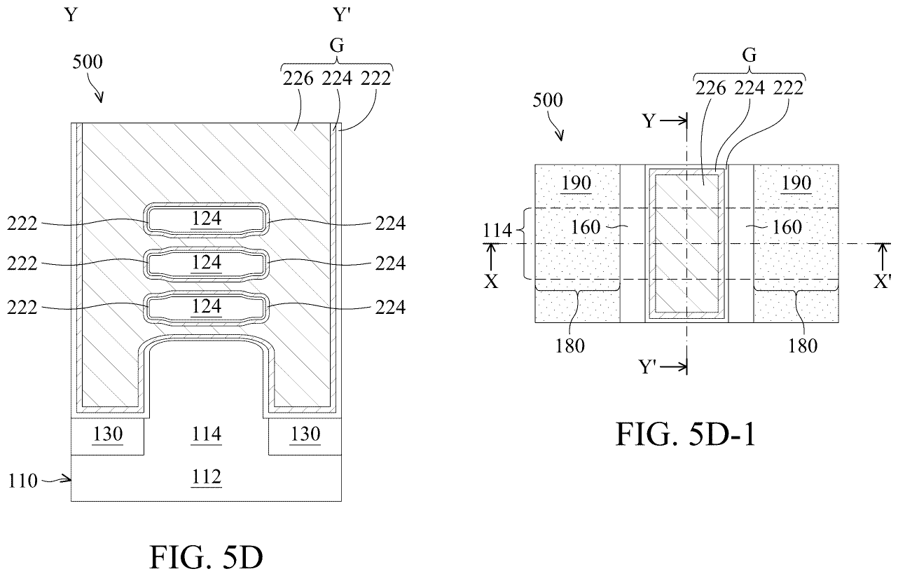

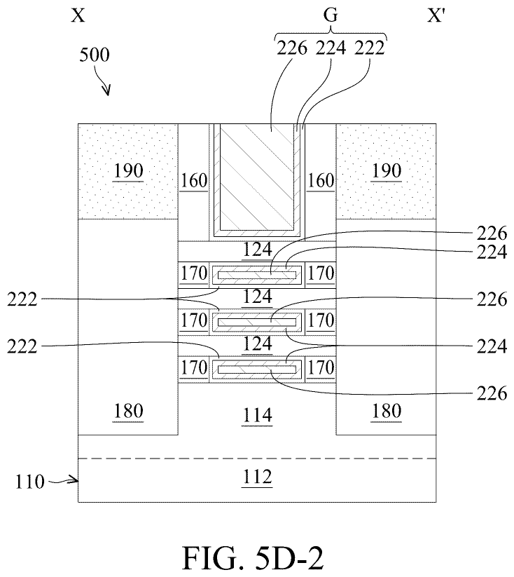

FIGS. 5A-5D are cross-sectional views of various stages of a process for forming a semiconductor device structure, in accordance with some embodiments. As shown in FIG. 5A, the step of FIG. 4D is performed to remove end potions of the nanostructures 122, in accordance with some embodiments.

As shown in FIGS. 5A and 5B, an etching process is performed on the nanostructures 124 and the fin 114 to remove surface portions of the nanostructures 124 and the fin 114, in accordance with some embodiments.

Since the etching rate of the corners C1, C2, and C3 is greater than that of the top surfaces 124c, the sidewalls 124b, and the bottom surfaces 124a of the nanostructures 124 and the top surface 114a and the sidewalls 114b of the fin 114, the etching process rounds the corners C1, C2, and C3, in accordance with some embodiments.

The corners C1 become rounded corners C1′ after the etching process is performed, in accordance with some embodiments. The corners C2 become rounded corners C2′ or C2″ after the etching process is performed, in accordance with some embodiments. The corners C3 become rounded corners C3′ after the etching process is performed, in accordance with some embodiments.

After the etching process is performed, the nanostructure 124 has concave lower surfaces 124d and concave upper surfaces 124e, and the fin 114 has concave upper surfaces 114c and an upper surface 114d, in accordance with some embodiments. Each concave lower surface 124d is connected between the bottom surface 124a and the corresponding sidewall 124b, in accordance with some embodiments. Each rounded corner C1′ is between the corresponding sidewall 124b and the corresponding concave lower surface 124d, in accordance with some embodiments.

Each concave upper surface 124e is connected between the top surface 124c and the corresponding sidewall 124b, in accordance with some embodiments. Each rounded corner C2′ is between the corresponding sidewall 124b and the corresponding concave upper surface 124e, in accordance with some embodiments.

The topmost one of the nanostructures 124 has rounded corners C2″, in accordance with some embodiments. Each rounded corner C2″ is between the corresponding sidewall 124b and the top surface 124c, in accordance with some embodiments.

Each concave upper surface 114c is connected between the top surface 114a and the corresponding sidewall 114b of the fin 114, in accordance with some embodiments. Each rounded corner C3′ is between the corresponding sidewall 114b and the corresponding concave upper surface 114c, in accordance with some embodiments.

The upper surface 114d is connected between the sidewall 114b and a lower sidewall 114e of the fin 114, in accordance with some embodiments. The upper surface 114d is substantially level with a top surface 132 of the isolation layer 130, in accordance with some embodiments. The sidewall 114b is misaligned with the lower sidewall 114e of the fin 114, in accordance with some embodiments.

The etching process includes an isotropic etching process, in accordance with some embodiments. The etching process includes a wet etching process or a dry etching process, in accordance with some embodiments. The etchant of the wet etching process includes NH₄OH, in accordance with some embodiments. The etchant of the dry etching process includes NH₃ and F₂, in accordance with some embodiments.

FIG. 5C-1 is a top view of the semiconductor device structure of FIG. 5C, in accordance with some embodiments. FIG. 5C is a cross-sectional view illustrating the semiconductor device structure along a sectional line Y-Y′ in FIG. 5C-1, in accordance with some embodiments. FIG. 5C-2 is a cross-sectional view illustrating the semiconductor device structure along a sectional line X-X′ in FIG. 5C-1, in accordance with some embodiments.

As shown in FIGS. 5C, 5C-1, and 5C-2, the nanostructures 122 are removed, in accordance with some embodiments. The removal process includes an etching process such as a dry etching process, in accordance with some embodiments. The etchant of the dry etching process includes F₂ and HF, in accordance with some embodiments.

FIG. 5D-1 is a top view of the semiconductor device structure of FIG. 5D, in accordance with some embodiments. FIG. 5D is a cross-sectional view illustrating the semiconductor device structure along a sectional line Y-Y′ in FIG. 5D-1, in accordance with some embodiments. FIG. 5D-2 is a cross-sectional view illustrating the semiconductor device structure along a sectional line X-X′ in FIG. 5D-1, in accordance with some embodiments.

As shown in FIGS. 5D, 5D-1, and 5D-2, the steps of FIGS. 2B and 2C are performed to form the gate stack G, in accordance with some embodiments. In this step, a semiconductor device structure 500 is substantially formed, in accordance with some embodiments.

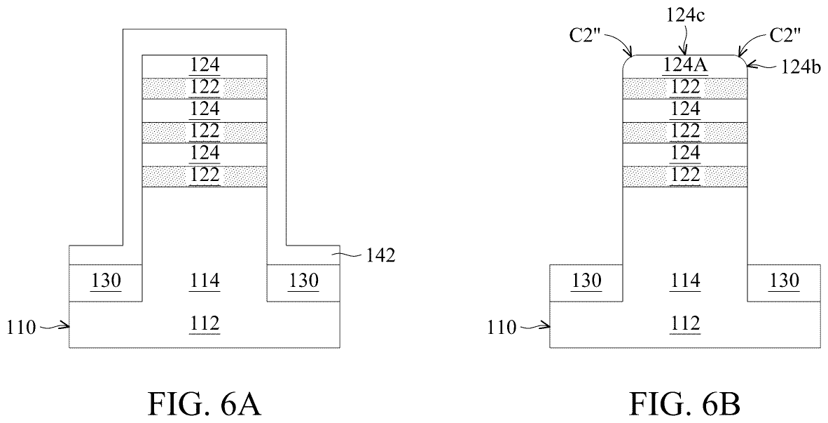

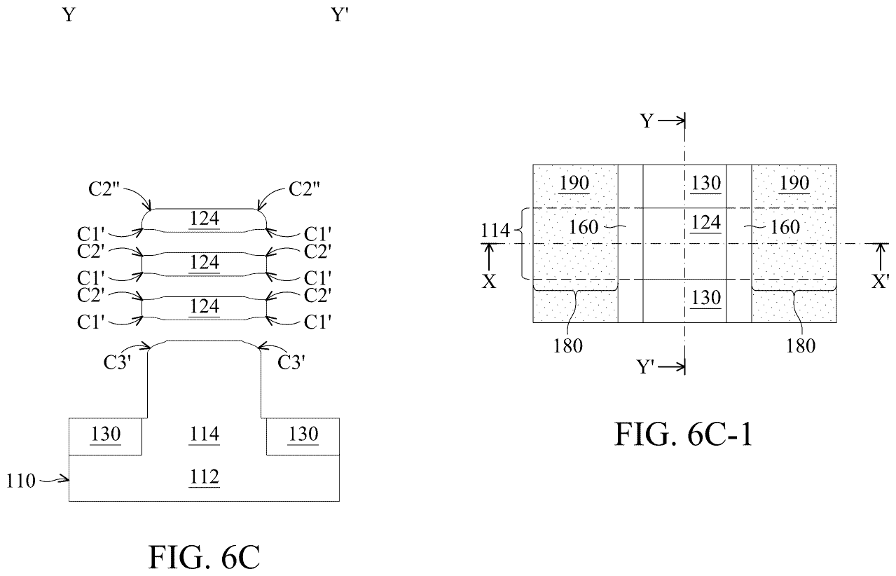

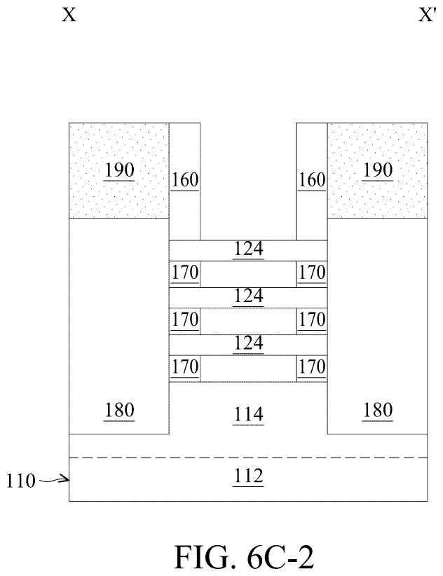

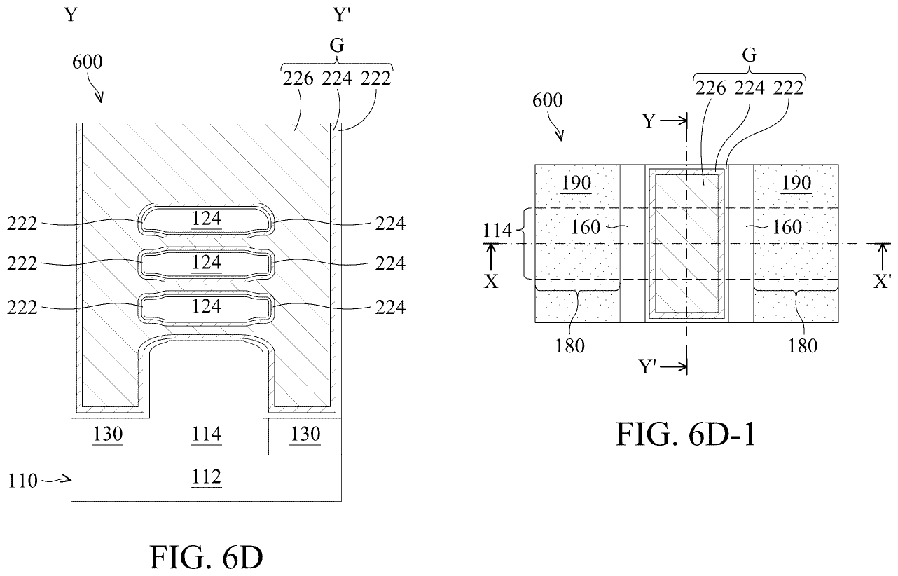

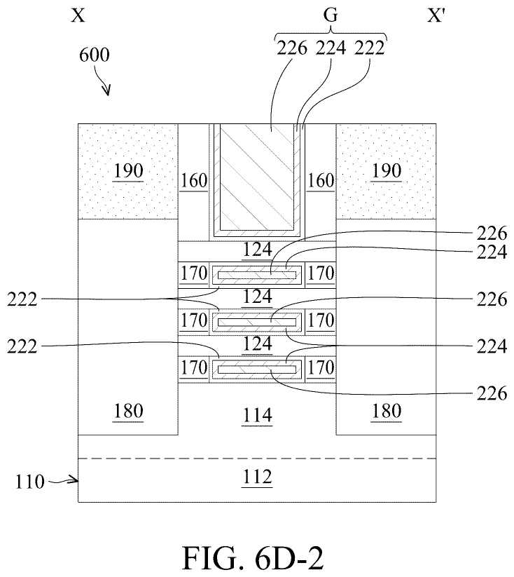

FIGS. 6A-6D are cross-sectional views of various stages of a process for forming a semiconductor device structure, in accordance with some embodiments. As shown in FIG. 6A, the step of FIG. 4B is performed to remove the mask layer 150 and the gate electrode 144, in accordance with some embodiments. The removal process includes an etching process such as a wet etching process or a dry etching process, in accordance with some embodiments.

As shown in FIG. 6B, the gate dielectric layer 142 is removed, in accordance with some embodiments. The nanostructure 124A is the topmost one of the nanostructures 124, in accordance with some embodiments. The removal process may also remove portions of the nanostructure 124A, in accordance with some embodiments. Therefore, the nanostructure 124A has rounded corners C2″, in accordance with some embodiments.

The rounded corner C2″ is between the top surface 124c and the sidewall 124b of the nanostructure 124A, in accordance with some embodiments. The removal process includes an etching process such as a wet etching process or a dry etching process, in accordance with some embodiments.

FIG. 6C-1 is a top view of the semiconductor device structure of FIG. 6C, in accordance with some embodiments. FIG. 6C is a cross-sectional view illustrating the semiconductor device structure along a sectional line Y-Y′ in FIG. 6C-1, in accordance with some embodiments. FIG. 6C-2 is a cross-sectional view illustrating the semiconductor device structure along a sectional line X-X′ in FIG. 6C-1, in accordance with some embodiments.

As shown in FIGS. 6C, 6C-1, and 6C-2, the steps of FIGS. 4D-4G or the steps of the FIGS. 5A-5C are performed to remove the nanostructures 122 and to form the rounded corners C1′, C2′, and C3′, in accordance with some embodiments.

Since the rounded corners C2″ are formed before the rounded corners C1′, C2′, and C3′ are formed, the rounded corners C2″ are rounder than the rounded corners C1′, C2′, and C3′ after the oxidation process of FIG. 4E or the etching process of FIG. 5B, in accordance with some embodiments.

FIG. 6D-1 is a top view of the semiconductor device structure of FIG. 6D, in accordance with some embodiments. FIG. 6D is a cross-sectional view illustrating the semiconductor device structure along a sectional line Y-Y′ in FIG. 6D-1, in accordance with some embodiments. FIG. 6D-2 is a cross-sectional view illustrating the semiconductor device structure along a sectional line X-X′ in FIG. 6D-1, in accordance with some embodiments.

As shown in FIGS. 6D, 6D-1, and 6D-2, the step of FIG. 4H is performed to form the gate stack G, in accordance with some embodiments. In this step, a semiconductor device structure 600 is substantially formed, in accordance with some embodiments.

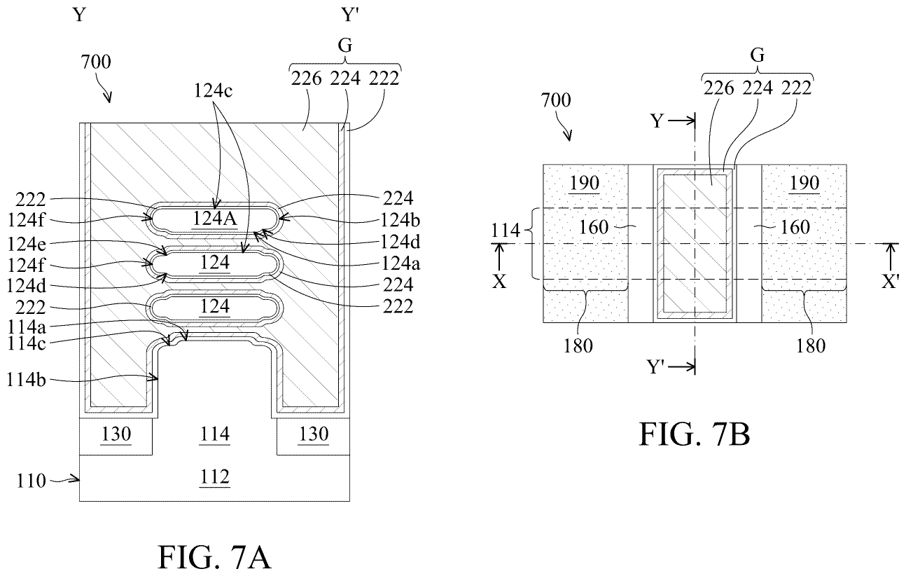

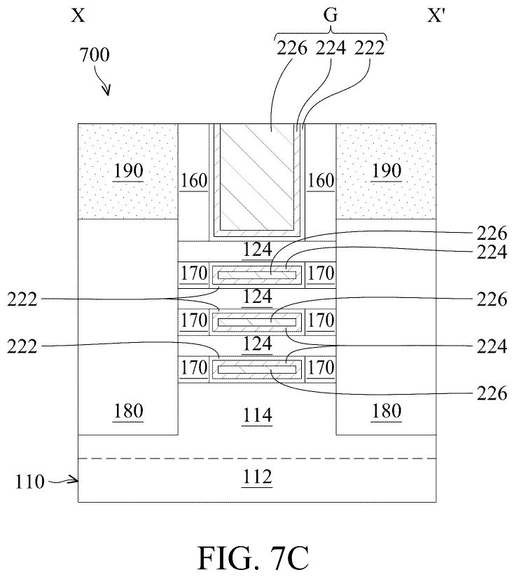

FIG. 7A is a cross-sectional view of a semiconductor device structure 700, in accordance with some embodiments. FIG. 7B is a top view of the semiconductor device structure 700 of FIG. 7A, in accordance with some embodiments.

FIG. 7A is a cross-sectional view illustrating the semiconductor device structure 700 along a sectional line Y-Y′ in FIG. 7B, in accordance with some embodiments. FIG. 7C is a cross-sectional view illustrating the semiconductor device structure 700 along a sectional line X-X′ in FIG. 7B, in accordance with some embodiments.

As shown in FIGS. 7A, 7B, and 7C, the semiconductor device structure 700 is similar to the semiconductor device structure 100 of FIG. 2C, except that the nanostructure 124 has convex curved sidewalls 124f, in accordance with some embodiments.

The convex curved sidewalls 124f is connected between the concave upper surface 124e and the concave lower surface 124d of the nanostructure 124, in accordance with some embodiments. The concave upper surface 124e is connected between the top surface 124c and the convex curved sidewall 124f, in accordance with some embodiments. In some other embodiments, the convex curved sidewalls 124f is connected between the top surface 124c and the concave lower surface 124d of the nanostructure 124A.

The formation process of the semiconductor device structure 700 is similar to that of FIGS. 1A-2C, 3A-3D, 4A-4H or 5A-5D, except that the formation process of the semiconductor device structure 700 removes more portions of the nanostructures 124 than that of FIGS. 1A-2C, 3A-3D, 4A-4H or 5A-5D, in accordance with some embodiments.

For example, the oxidation process used to form the semiconductor device structure 700 includes a thermal oxidation process, which can oxidize more nanostructures 124 than a chemical oxidation process.

Processes and materials for forming the semiconductor structures 300, 400, 500, 600, and 700 may be similar to, or the same as, those for forming the semiconductor structure 100 described above. Elements designated by the same reference numbers as those in FIGS. 1A to 7C have the structures and the materials similar thereto or the same thereas. Therefore, the detailed descriptions thereof will not be repeated herein.

In accordance with some embodiments, semiconductor device structures and methods for forming the same are provided. The methods (for forming the semiconductor device structure) form nanostructures and a fin with rounded corners to improve the coverage of a gate dielectric layer on the nanostructures and the fin, which improves the yield of the gate dielectric layer and the reliability of the semiconductor device structures.

In accordance with some embodiments, a method for forming a semiconductor device structure is provided. The method includes providing a substrate, a first nanostructure, a second nanostructure, and a first gate stack. The first nanostructure is between the substrate and the second nanostructure, and the first gate stack is wrapped around the first nanostructure and the second nanostructure. The method includes removing the first gate stack and end potions of the first nanostructure. The method includes partially removing the second nanostructure to round a first corner of the second nanostructure. The first corner becomes a first rounded corner after the second nanostructure is partially removed. The method includes removing the first nanostructure. The method includes forming a second gate stack over the substrate and wrapped around the second nanostructure.

In accordance with some embodiments, a semiconductor device structure is provided. The semiconductor device structure includes a substrate. The semiconductor device structure includes a nanostructure over the substrate. The nanostructure has a bottom surface, a first sidewall, and a concave lower surface connected between the bottom surface and the first sidewall, and the nanostructure has a first rounded corner between the first sidewall and the concave lower surface. The semiconductor device structure includes a gate stack wrapped around the nanostructure.

In accordance with some embodiments, a semiconductor device structure is provided. The semiconductor device structure includes a substrate. The semiconductor device structure includes a nanostructure over the substrate. The nanostructure has a first concave upper surface, a concave lower surface, and a convex curved sidewall connected between the first concave upper surface and the concave lower surface. The semiconductor device structure includes a gate stack wrapped around the nanostructure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor device structure, comprising:
providing a substrate, a first nanostructure, a second nanostructure, and a first gate stack, wherein the first nanostructure is between the substrate and the second nanostructure, and the first gate stack wraps around the first nanostructure and the second nanostructure;
removing the first gate stack and end potions of the first nanostructure;
partially removing the second nanostructure to round a first corner of the second nanostructure, wherein the first corner becomes a first rounded corner after the second nanostructure is partially removed;
removing the first nanostructure; and
forming a second gate stack over the substrate, wherein the second gate stack wraps around the second nanostructure.

2. The method of claim 1, wherein the first gate stack comprises a gate dielectric layer and a gate electrode over the gate dielectric layer, the gate dielectric layer is made of a first oxide material, and the first nanostructure is made of a second oxide material.

3. The method of claim 2, wherein the removing of the first gate stack and the end potions of the first nanostructure comprises:
removing the gate electrode; and
removing the gate dielectric layer and the end potions of the first nanostructure.

4. The method of claim 3, wherein the partially removing of the second nanostructure comprises:
performing an oxidation process on the substrate and the second nanostructure to form an oxide layer on the substrate and the second nanostructure; and
removing the oxide layer.

5. The method of claim 3, wherein the partially removing of the second nanostructure comprises:
performing an etching process on the second nanostructure.

6. The method of claim 5, wherein the etching process comprises an isotropic etching process.

7. The method of claim 1, wherein the first gate stack comprises a gate dielectric layer and a gate electrode over the gate dielectric layer, and the first nanostructure and the gate dielectric layer are made of different materials.

8. The method of claim 7, wherein the removing of the first gate stack and the end potions of the first nanostructure comprises:
removing the gate electrode;
removing the gate dielectric layer; and
removing the end potions of the first nanostructure.

9. The method of claim 8, wherein the partially removing of the second nanostructure comprises:
performing an oxidation process on the substrate, the first nanostructure, and the second nanostructure to form an oxide layer on the substrate, the first nanostructure, and the second nanostructure; and
removing the oxide layer.

10. The method of claim 8, wherein the partially removing of the second nanostructure comprises:
performing an etching process on the second nanostructure.

11. A semiconductor structure, comprising:
a substrate;
a nanostructure over the substrate, wherein the nanostructure has a bottom surface, a first sidewall, and a curved lower surface connected between the bottom surface and the first sidewall, and the nanostructure has a first rounded corner between the first sidewall and the curved lower surface; and
a gate stack wrapped around the nanostructure.

12. The semiconductor structure of claim 11, wherein the gate stack comprises a gate dielectric layer and a gate electrode over the gate dielectric layer, and the gate dielectric layer conformally covers the bottom surface, the first sidewall, and the curved lower surface of the nanostructure.

13. The semiconductor structure of claim 11, wherein the nanostructure has a top surface and a concave upper surface connected between the top surface and the first sidewall.

14. The semiconductor structure of claim 13, wherein the nanostructure has a second rounded corner between the concave upper surface and the first sidewall.

15. The semiconductor structure of claim 11, wherein the substrate comprises a base and a fin over the base, the fin has a top surface, a second sidewall, and a concave upper surface connected between the top surface and the second sidewall.

16. The semiconductor structure of claim 15, wherein the fin has a second rounded corner between the second sidewall and the concave upper surface.

17. The semiconductor structure of claim 15, wherein the concave upper surface of the fin is under the curved lower surface of the nanostructure, and the second sidewall of the fin is under the first sidewall of the nanostructure.

18. A semiconductor structure, comprising:
a substrate;
a nanostructure over the substrate, wherein the nanostructure has a first concave upper surface, a concave lower surface, and a convex curved sidewall connected between the first concave upper surface and the concave lower surface; and
a gate stack wrapped around the nanostructure.

19. The semiconductor structure of claim 18, wherein the nanostructure has a substantially flat top surface, and the first concave upper surface is connected between the substantially flat top surface and the convex curved sidewall.

20. The semiconductor structure of claim 18, wherein the substrate comprises a base and a fin over the base, the fin has a top surface, a sidewall, and a second concave upper surface connected between the top surface and the sidewall, the concave lower surface of the nanostructure is between the first concave upper surface of the nanostructure and the second concave upper surface of the fin.
